(19) United States
(12) Patent Application Publication
(10) Pub. No.: US 2015/0263162 A1
(43) Pub. Date: Sep. 17, 2015

(54) SEMICONDUCTOR DEVICE

(71) Applicant: Kabushiki Kaisha Toshiba, Tokyo (JP)

(72) Inventors: Toshifumi Nishiguchi, Nonoichi Ishikawa (JP); Hideki Okumura, Nonoichi Ishikawa (JP)

(21) Appl. No.: 14/482,309

(22) Filed: Sep. 10, 2014

(30) Foreign Application Priority Data
Mar. 17, 2014 (JP) 2014-053743

(51) Int. Cl. H01L 29/78; H01L 29/06; H01L 29/423

(52) U.S. Cl. CPC H01L 29/7813; H01L 29/4236; H01L 29/0696

(57) ABSTRACT

In one embodiment, a semiconductor device includes first, second, third, fourth, fifth and sixth electrodes extending in a first direction, the third and fourth electrodes being provided to sandwich the first electrode, the fifth and sixth electrodes being provided to sandwich the second electrode, the first, second, fifth and sixth electrodes being electrically connected with one another, and the third and fourth electrodes being electrically connected with each other and electrically independent from the first, second, fifth and sixth electrodes. The device further includes a semiconductor layer provided between one of the third and fourth electrodes and one of the fifth and sixth electrodes. The device further includes a first interconnect provided on the second, fifth and sixth electrodes and on the semiconductor layer.

### CROSS REFERENCE TO RELATED APPLICATION

This application is based upon and claims the benefit of priority from the prior Japanese Patent Application No. 2014-53743, filed on Mar. 17, 2014, the entire contents of which are incorporated herein by reference.

### FIELD

Embodiments described herein relate to a semiconductor device.

### BACKGROUND

A power semiconductor device is required to have a high drain voltage, a low on-resistance, and a low on-resistance capacitance product. The on-resistance capacitance product refers to a product of the on-resistance and a capacitance. To meet these requirements, there has been considered a configuration in which some of gate electrodes of the power semiconductor device are supplied with a source potential in place of a gate potential (hereinafter, these gate electrodes are referred to as “source-gate electrodes”). In this case, a channel area is decreased and the on-resistance is increased. However, since a percentage of a channel resistivity in a total resistivity is small (for example, about 5%), an increase of the on-resistance is small in this case. On the other hand, since the decrease in the channel area has a large influence on the capacitance, a decrease of the on-resistance capacitance product is large in this case (for example, about 50%). Therefore, when some of the gate electrodes of the power semiconductor device are the source-gate electrodes, it is possible to suppress an increase of the on-resistance while decreasing the on-resistance capacitance product. However, when some of the gate electrodes of the power semiconductor device are the source-gate electrodes, there is a problem that it becomes difficult to form a contact interconnect on a semiconductor layer between a normal gate electrode and a source-gate electrode in accordance with the shrink of the power semiconductor device.

### BRIEF DESCRIPTION OF THE DRAWINGS

FIGS. 1 and 2 are a plan view and a sectional view illustrating a structure of a semiconductor device of a first embodiment, respectively;

FIGS. 3 and 4 are a plan view and a sectional view illustrating a structure of a semiconductor device of a comparative example of the first embodiment, respectively; and

FIGS. 5 and 6 are a plan view and a sectional view illustrating a structure of a semiconductor device of a second embodiment, respectively.

### DETAILED DESCRIPTION

Embodiments will now be explained with reference to the accompanying drawings.

In one embodiment, a semiconductor device includes first, second, third, fourth, fifth and sixth electrodes extending in a first direction, the third and fourth electrodes being provided to sandwich the first electrode, the fifth and sixth electrodes being provided to sandwich the second electrode, the first, second, fifth and sixth electrodes being electrically connected with one another, and the third and fourth electrodes being electrically connected with each other and electrically independent from the first, second, fifth and sixth electrodes. The device further includes a semiconductor layer provided between one of the third and fourth electrodes and one of the fifth and sixth electrodes. The device further includes a first interconnect provided on the second, fifth and sixth electrodes and on the semiconductor layer.

### First Embodiment

### (1) Structure of Semiconductor Device of First Embodiment

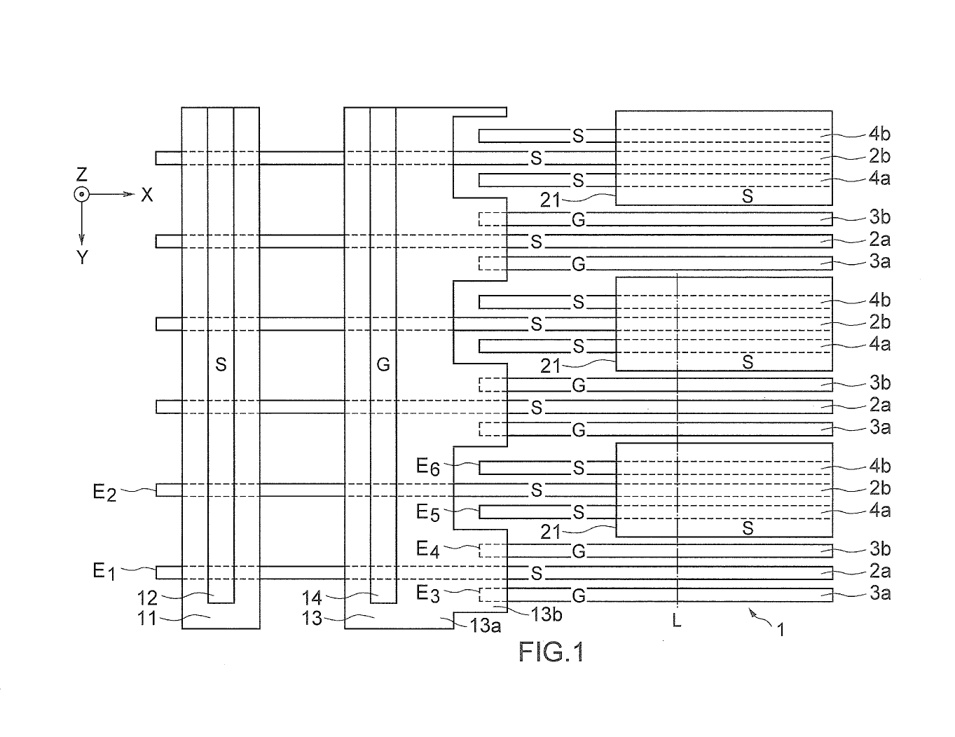

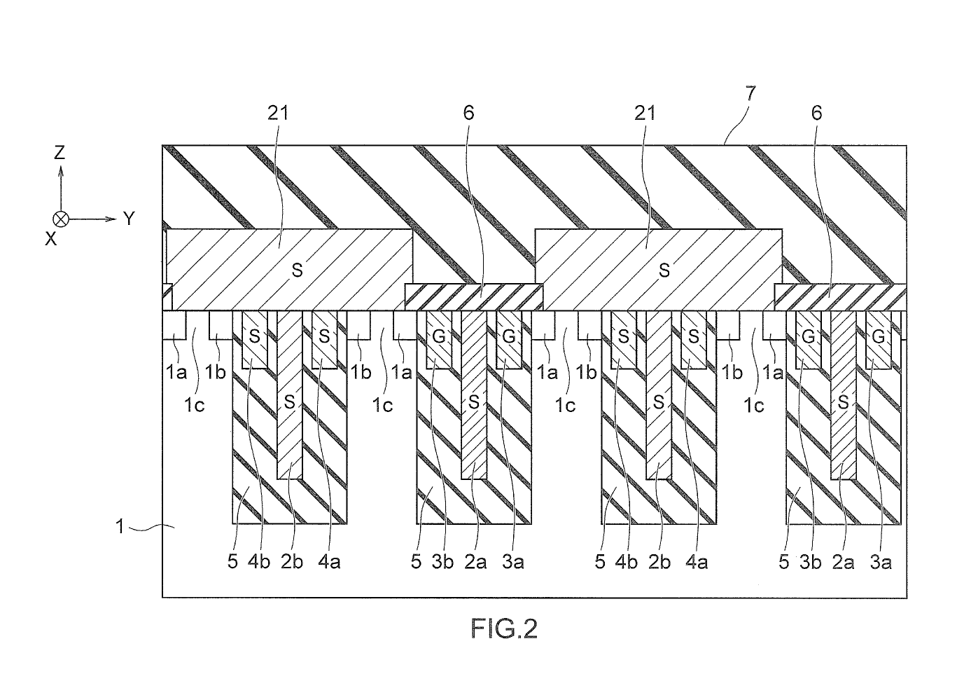

FIGS. 1 and 2 are a plan view and a sectional view illustrating a structure of a semiconductor device of a first embodiment, respectively. The device of the present embodiment is a power semiconductor device including a trench gate type MOSFET. FIG. 2 illustrates a section taken along the line L illustrated in FIG. 1.

Hereinafter, the structure of the semiconductor device of the present embodiment is described mainly with reference to FIG. 1, and also with reference to FIG. 2 as necessary in this description.

The device of the present embodiment includes a substrate 1, first and second source electrodes 2a and 2b as an example of first and second electrodes, first and second gate electrodes 3a and 3b as an example of third and fourth electrodes, first and second source-gate electrodes 4a and 4b as an example of fifth and sixth electrodes, first insulators 5, second insulators 6, and a third insulator 7. Illustration of the first, second and third insulators 5, 6 and 7 is omitted in FIG. 1.

The device of the present embodiment further includes a source interconnect 11, a source contact interconnect 12, a gate interconnect 13, a gate contact interconnect 14, and first contact interconnects 21 as an example of a first interconnect.

An example of the substrate 1 is a semiconductor substrate such as a silicon substrate. FIGS. 1 and 2 illustrate an X direction and a Y direction which are parallel to the substrate 1 and perpendicular with each other, and a Z direction which is perpendicular with the substrate 1. The X direction is an example of a first direction, and the Y direction is an example of a second direction which is different from the first direction. In this specification, a +Z direction is handled as an upward direction, and an −Z direction is handled as a downward direction. For example, a positional relationship between the substrate 1 and the third insulator 7 in FIG. 2 is expressed that the substrate 1 is positioned below the third insulator 7.

The first and second source electrodes 2a and 2b are formed on the substrate 1, extend in the X direction, and are supplied with a source potential which is an example of a first potential. An example of the first and second source electrodes 2a and 2b is polysilicon layers. In the present embodiment, a plurality of first source electrodes 2a and a plurality of second source electrodes 2b are alternately arranged along the Y direction. Reference numerals E₁ and E₂ denote end portions of the first and second source electrodes 2a and 2b, respectively.

The first and second gate electrodes 3a and 3b extend in the X direction, are arranged on the substrate 1 so as to sandwich the first source electrode 2a, and are supplied with a gate potential which is an example of a second potential different from the first potential. An example of the first and second gate electrodes 3a and 3b is polysilicon layers. Reference numerals E₃ and E₄ denote end portions of the first and second gate electrodes 3a and 3b, respectively.

The first and second source-gate electrodes 4a and 4b extend in the X direction, are arranged on the substrate 1 so as to sandwich the second source electrode 2b, and are supplied with the source potential. An example of the first and second source-gate electrodes 4a and 4b is polysilicon layers. Reference numerals E₅ and E₆ denote end portions of the first and second source-gate electrodes 4a and 4b, respectively.

The first and second source electrodes 2a and 2b and the first and second source-gate electrodes 4a and 4b are electrically connected with an unshown source line provided above the substrate 1, and are supplied with the source potential from the source line. The first and second source electrodes 2a and 2b and the first and second source-gate electrodes 4a and 4b are electrically connected with one another via the source line.

The first and second gate electrodes 3a and 3b are electrically connected with an unshown gate line provided above the substrate 1, and are supplied with the gate potential from the gate line. The first and second gate electrodes 3a and 3b are electrically connected with each other via the gate line, and are electrically independent from the first and second source electrodes 2a and 2b and the first and second source-gate electrodes 4a and 4b.

The first insulators 5 (FIG. 2) are formed on the substrate 1 so as to extend in the X direction. Each of the first insulators 5 contacts side and bottom portions of the first source electrode 2a and the first and second gate electrodes 3a and 3b, or side and bottom portions of the second source electrode 2b and the first and second source-gate electrodes 4a and 4b. An example of the first insulators 5 are silicon oxide films.

The second insulators 6 (FIG. 2) are formed on the substrate 1 so as to extend in the X direction. Each of the second insulators 6 contact top portions of the first source electrode 2a and the first and second gate electrodes 3a and 3b. An example of the second insulators 6 are silicon oxide films.

The third insulator 7 (FIG. 2) is formed on the substrate 1 so as to cover the source interconnect 11, the source contact interconnect 12, the gate interconnect 13, the gate contact interconnect 14, and the first contact interconnects 21. An example of the third insulator 7 is a silicon oxide film.

As illustrated in FIG. 2, the substrate 1 includes a first source layers 1a as an example of a first semiconductor layer, a second source layer 1b as an example of a second semiconductor layer, and a base layer 1c as an example of a third semiconductor layer between each pair of adjacent first insulators 5.

The first source layer 1a, the second source layer 1b, and the base layer is are formed between a first or second gate electrode 3a or 3b and a first or second source-gate electrode 4a or 4b via the first insulators 5. The first source layer 1a is an n-type layer, and is adjacent to the first or second gate electrode 3a or 3b. The second source layer 1b is an n-type layer, and is adjacent to the first or second source-gate electrode 4a or 4b. The base layer 1c is a p-type layer, and includes a portion formed between the first and second source layers 1a and 1b. The n conductivity type and the p conductivity type are examples of first and second conductivity types, respectively.

The source interconnect 11 is formed on the substrate 1 so as to extend in the Y direction. An example of the source interconnect 11 is a polysilicon layer. The source contact interconnect 12 is formed on the source interconnect 11 so as to extend in the Y direction. An example of the source contact interconnect 12 is a metal layer. The source interconnect 11 is formed on the first and second source electrodes 2a and 2b, and supplies the first and second source electrodes 2a and 2b with the source potential. The source interconnect 11 and the source contact interconnect 12 are supplied with the source potential from the source line.

The gate interconnect 13 is formed on the substrate 1 so as to extend in the Y direction, and is positioned in a +X direction of the source interconnect 11. An example of the gate interconnect 13 is a polysilicon layer. The gate contact interconnect 14 is formed on the gate interconnect 13 so as to extend in the Y direction. An example of the gate contact interconnect 14 is a metal layer. The gate interconnect 13 is formed on the first and second gate electrodes 3a and 3b, and supplies the first and second gate electrodes 3a and 3b with the gate potential. The gate interconnect 13 is formed on the first and second source electrodes 2a and 2b via an insulator, and electrically insulated from the first and second source electrodes 2a and 2b. The gate interconnect 13 and the gate contact interconnect 14 are supplied with the gate potential from the gate line.

The gate interconnect 13 has a comb shape. Specifically, the gate interconnect 13 includes a first region 13a having a belt shape extending in the Y direction, and second regions 13b positioned in the +X direction of the first region 13a. A pitch between the second regions 13b is same as a pitch between the first source electrodes 2a and a pitch between the second source electrodes 2b. The end portions E₁ and E₂ of the first and second source electrodes 2a and 2b are positioned in an −X direction of the source interconnect 11 and the gate interconnect 13. The end portions E₃ and E₄ of the first and second gate electrodes 3a and 3b are positioned in the +X direction of the source interconnect 11, and are positioned immediately under the second regions 13b of the gate interconnect 13. The end portions E₅ and E₆ of the first and second source-gate electrodes 4a and 4b are positioned in the +X direction of the source interconnect 11 and the gate interconnect 13. Therefore, the end portions E₁ and E₂ of the first and second source electrodes 2a and 2b are positioned on an opposite side of the end portions E₅ and E₆ of the first and second source-gate electrodes 4a and 4b relative to the source interconnect 11 and the gate interconnect 13. The end portions E₅ and E₆ of the first and second source-gate electrodes 4a and 4b are positioned between the second regions 13b of the gate interconnect 13.

The first contact interconnects 21 are formed on the substrate 1 so as to extend in the X direction. An example of the first contact interconnects 21 are metal layers. Unlike the source contact interconnect 12 and the gate contact interconnect 14, each first contact interconnect 21 is formed on the substrate 1 without interposing a polysilicon layer. A pitch between the first contact interconnects 21 is same as the pitch between the first source electrodes 2a and the pitch between the second source electrodes 2b.

As illustrated in FIG. 2, the first contact interconnects 21 are formed on the second source electrodes 2b, the first and second source-gate electrodes 4a and 4b, the first and second source layers 1a and 1b, and the base layers 1c. Therefore, the first contact interconnects 21 can supply the second source electrodes 2b, the first and second source-gate electrodes 4a and 4b, the first and second source layers 1a and 1b, and the base layers is with the source potential. The first contact interconnects 21 are electrically connected with these electrodes and these semiconductor layers, but are electrically insulated from the first and second gate electrodes 3a and 3b. The first contact interconnects 21 are supplied with the source potential from the source line.

### (2) Structure of Semiconductor Device of Comparative Example of First Embodiment

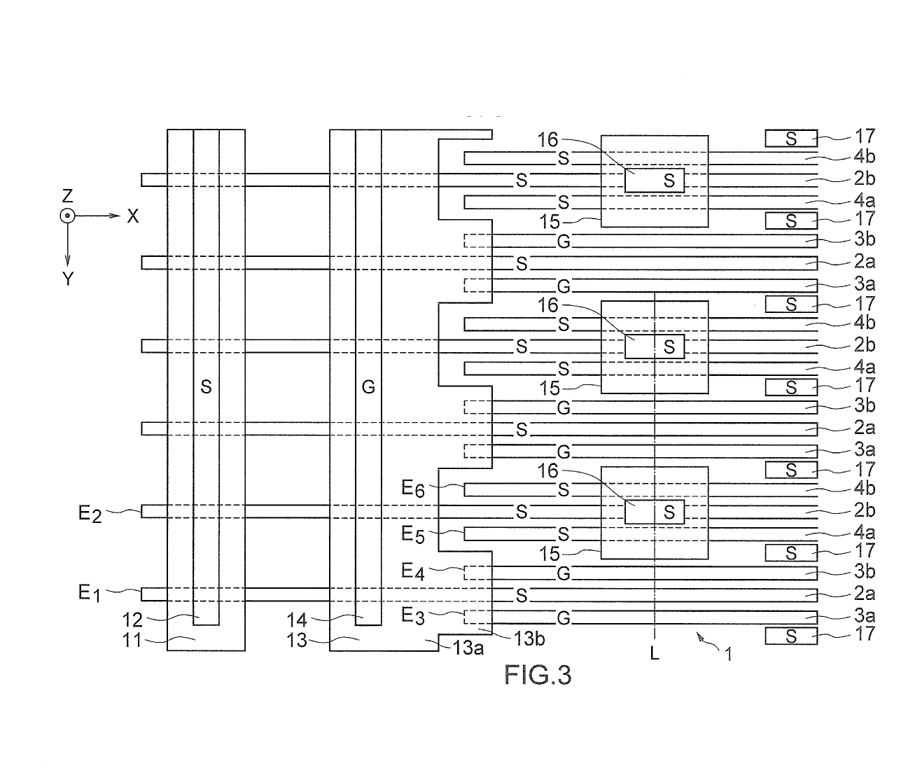

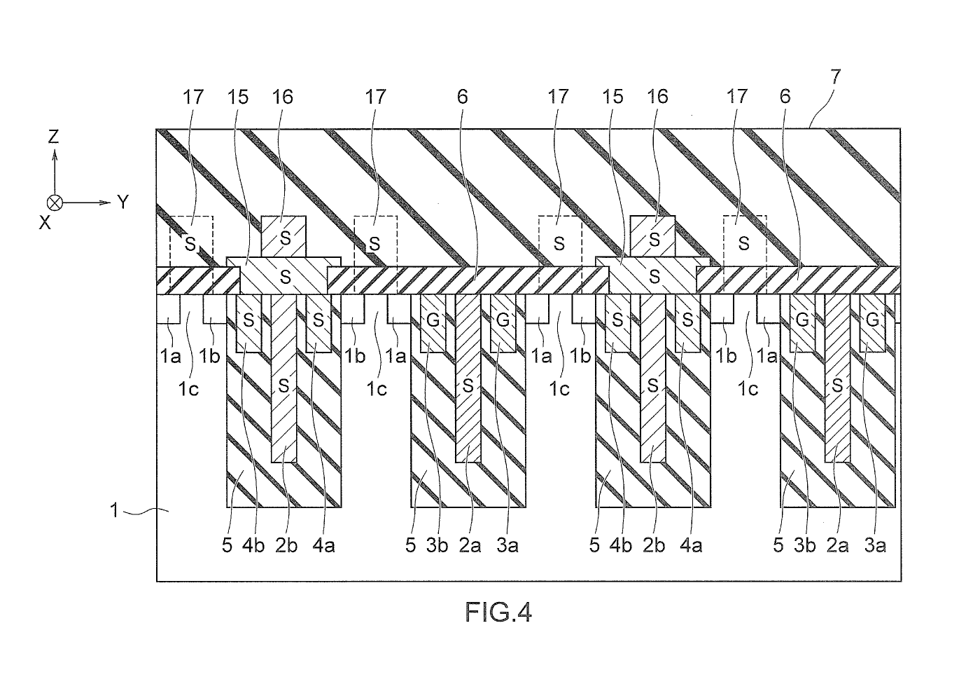

FIGS. 3 and 4 are a plan view and a sectional view illustrating a structure of a semiconductor device of a comparative example of the first embodiment, respectively. FIG. 4 illustrates a section taken along the line L illustrated in FIG. 3.

Hereinafter, the structure of the semiconductor device of the comparative example is described mainly with reference to FIG. 3, and also with reference to FIG. 4 as necessary in this description.

In the comparative example, each of the first contact interconnects 21 of the first embodiment is replaced with a source gate interconnect 15, a source gate contact interconnect 16, and contact interconnects 17.

As illustrated in FIG. 4, the source gate interconnect 15 is formed on a second source electrode 2b and first and second source-gate electrodes 4a and 4b. Therefore, the source gate interconnect 15 can supply the second source electrode 2b and the first and second source-gate electrodes 4a and 4b with the source potential. An example of the source gate interconnect 15 is a polysilicon layer. The source gate contact interconnect 16 is formed on the source gate interconnect 15. An example of the source gate contact interconnect 16 is a metal layer. The source gate interconnect 15 and the source gate contact interconnect 16 are supplied with the source potential from the source line.

FIG. 4 illustrates the contact interconnects 17 positioned in the +X direction of the line L with a dotted line. As illustrated in FIG. 4, each contact interconnect 17 is formed on first and second source layers 1a and 1b and a base layer 1c. Therefore, each contact interconnect 17 can supply the first and second source layers 1a and 1b and the base layer 1c with the source potential.

Each contact interconnect 17 is electrically connected with these semiconductor layers 1a to 1c, but are electrically insulated from the first and second gate electrodes 3a and 3b. An example of the contact interconnects 17 are metal layers. The contact interconnects 17 are supplied with the source potential from the source line.

Here, a comparison is made between the first embodiment and the comparative example.

As the shrink of the semiconductor device progresses in the comparative example, it becomes difficult to form the contact interconnects 17 on the semiconductor layers 1a to 1c. It is because as the shrink of the semiconductor device progresses, widths of the semiconductor layers 1a to is in the Y direction are decreased and a margin in lithography and etching for forming the contact interconnects 17 is decreased. An example of a width of the contact interconnects 17 in the Y direction is 0.25 to 0.35 μm.

In this case, the lithography may be performed by using a KrF laser having a wavelength of 248 nm, for example.

On the other hand, it is possible in the first embodiment to make the width of the first contact interconnects 21 in the Y direction wider than the width of the contact interconnects 17 in the Y direction. Therefore, even if the shrink of the semiconductor device is progressed, it is possible to secure a sufficient margin in the lithography and etching for forming the first contact interconnects 21. Therefore, it is possible to easily form the first contact interconnects 21. An example of the width of the first contact interconnects 21 in the Y direction is 3.0 to 3.5 μm. In this case, the lithography may be performed by using an i-line having a wavelength of 365 nm, for example.

Furthermore, the first contact interconnects 21 in the first embodiment are formed on the substrate 1 without interposing polysilicon layers, and an area of the first contact interconnects 21 within an XY plane is set to be larger than a total area of the interconnects 15 and 17 within the XY plane. Therefore, the present embodiment makes it possible to make resistance of the first contact interconnects 21 smaller than resistance of the interconnects 15, 16 and 17.

In the comparative example, plural source gate interconnects 15 and plural source gate contact interconnects 16 are arranged on each second source electrode 2b. In FIG. 3, one of the plural source gate interconnects 15 and one of the plural source gate contact interconnects 16 are illustrated on each second source electrode 2b.

On the other hand, in the first embodiment, only one first contact interconnect 21 is arranged on each second source electrode 2b. In other words, in the first embodiment, the plural source gate interconnects 15 and the plural source gate contact interconnects 16 of the comparative example are replaced with one first contact interconnect 21. Therefore, the present embodiment makes it possible to make the resistance of the first contact interconnects 21 significantly smaller than the resistance of the interconnects 15, 16 and 17.

As described above, the semiconductor device of the first embodiment includes the first contact interconnects 21, each of which is formed on a second source electrode 2b, first and second source-gate electrodes 4a and 4b, and semiconductor layers is to 1c, and configured to supply the second source electrode 2b, the first and second source-gate electrodes 4a and 4b, and the semiconductor layers 1a to is with the source potential.

Therefore, the present embodiment makes it possible to easily form the interconnects (first contact interconnects 21) on the semiconductor layers is to is between the first and second gate electrodes 3a and 3b and the first and second source-gate electrodes 4a and 4b.

### Second Embodiment

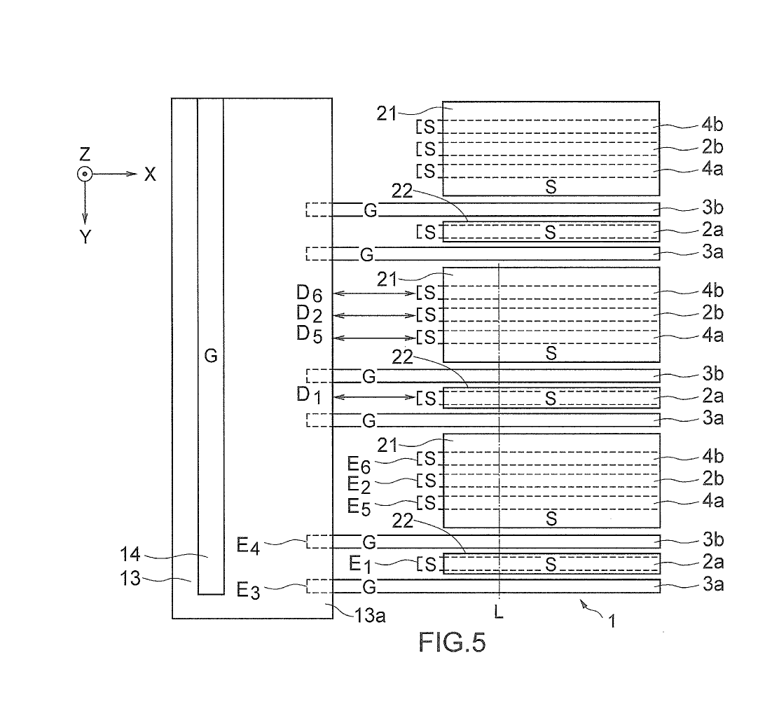

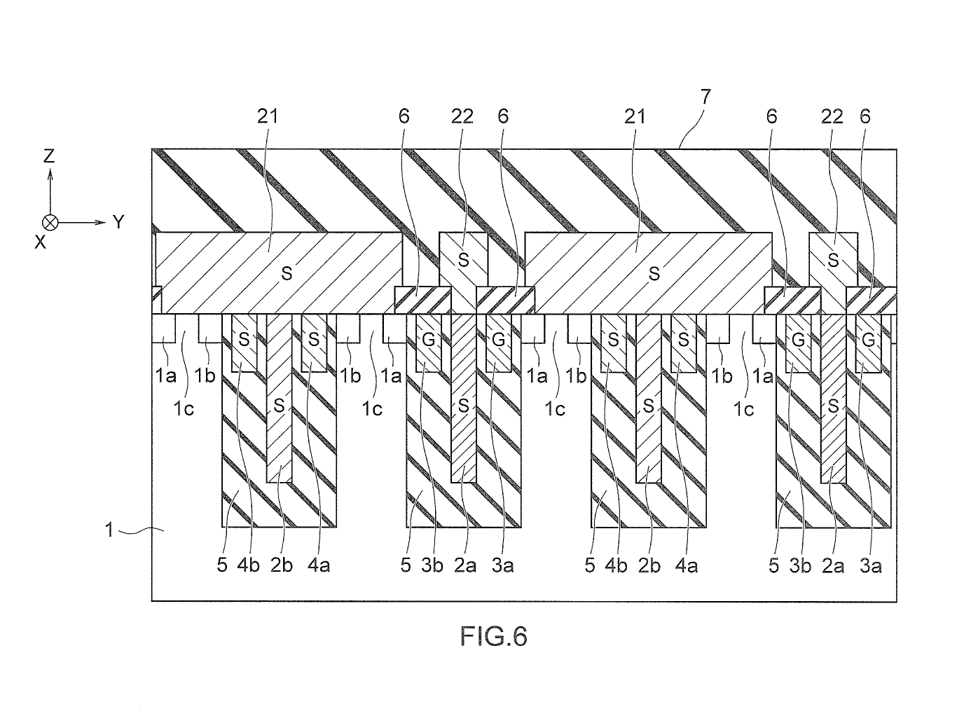

FIGS. 5 and 6 are a plan view and a sectional view illustrating a structure of a semiconductor device of a second embodiment, respectively. FIG. 6 illustrates a section taken along the line L illustrated in FIG. 5.

Hereinafter, the structure of the semiconductor device of the present embodiment is described mainly with reference to FIG. 5, and also with reference to FIG. 6 as necessary in this description.

In the second embodiment, the source interconnect 11 and the source contact interconnect 12 of the first embodiment are replaced with second contact interconnects 22. The second contact interconnects 22 are an example of a second interconnect. Furthermore, the gate interconnect 13 of the second embodiment has a non-comb shape. Therefore, the gate interconnect 13 of the second embodiment includes the first region 13a but does not include the second regions 13b.

The second contact interconnects 22 are formed on the substrate 1 so as to extend in the X direction. An example of the second contact interconnects 22 is metal layers. Similarly to the first contact interconnects 21, each second contact interconnect 22 is formed on the substrate 1 without interposing a polysilicon layer. A pitch between the second contact interconnects 22 is same as the pitch between the first source electrodes 2a and the pitch between the second source electrodes 2b.

As illustrated in FIGS. 5 and 6, each second contact interconnect 22 is formed on a first source electrode 2a so as to be sandwiched between first and second gate electrodes 3a and 3b. Therefore, each second contact interconnect 22 can supply the first source electrode 2a with the source potential. Each second contact interconnect 22 is electrically connected with the first source electrode 2a but is electrically insulated from the first and second gate electrodes 3a and 3b. Furthermore, the second contact interconnects 22 are isolated from the first contact interconnects 21 by the second and third insulators 6 and 7. The second contact interconnects 22 are supplied with the source potential from the source line.

In the present embodiment, only one second contact interconnect 22 is arranged on each first source electrode 2a. This is similar to the case where only one first contact interconnect 21 is arranged on each second source electrode 2b of the first embodiment.

The end portions E₁ and E₂ of the first and second source electrodes 2a and 2b are positioned in the +X direction of the gate interconnect 13. The end portions E₃ and E₄ of the first and second gate electrodes 3a and 3b are positioned immediately under the gate interconnect 13. The end portions E₅ and E₆ of the first and second source-gate electrodes 4a and 4b are positioned in the +X direction of the gate interconnect 13. Therefore, the end portions E₁ and E₂ of the first and second source electrodes 2a and 2b are positioned on the same side as the end portions E₅ and E₆ of the first and second source-gate electrodes 4a and 4b relative to the gate interconnect 13. Specifically, the X-directional positions of the end portions E₁ and E₂ are substantially same as the X-directional positions of the end portions E₅ and E₆, and the distances D₁ and D₂ between the end portions E₁ and E₂ and the gate interconnect 13 are set to be substantially same as the distances D₅ and D₆ between the end portions E₅ and E₆ and the gate interconnect 13.

Here, a comparison is made between the first and second embodiments.

In the first embodiment, the X-directional positions of the end portions E₃ and E₄ are substantially same as the X-directional positions of the end portions E₅ and E₆, and the X-directional lengths of the first and second gate electrodes 3a and 3b are substantially same as the X-directional lengths of the first and second source-gate electrodes 4a and 4b. This structure has an advantage that it is easy to form these electrodes 3a, 3b, 4a and 4b.

Furthermore, the gate interconnect 13 of the first embodiment has a comb shape. Therefore, the first embodiment makes it possible to set the X-directional lengths of the electrodes 3a, 3b, 4a, and 4b to be same while electrically connecting the electrodes 3a and 3b with the gate interconnect 13 and electrically insulating the electrodes 4a and 4b from the gate interconnect 13.

On the other hand, in the second embodiment, the X-directional positions of the end portions E₁ and E₂ are substantially same as the X-directional positions of the end portions E₅ and E₆, and the X-directional lengths of the first and second source electrodes 2a and 2b are substantially same as the X-directional lengths of the first and second source-gate electrodes 4a and 4b. This structure has an advantage that it is easy to form these electrodes 2a, 2b, 4a and 4b.

Furthermore, this structure has an advantage that it can increase the distances D₁, D₂, D₅ and D₆ between the gate interconnect 13 and the end portions E₁, E₂, E₅ and E₆. Therefore, the second embodiment makes it possible to suppress a situation in which the gate interconnect 13 is electrically connected with the end portions E₁, E₂, E₅ and E₆ by residue during etching of the gate interconnect 13.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
first, second, third, fourth, fifth and sixth electrodes extending in a first direction, the third and fourth electrodes being provided to sandwich the first electrode, the fifth and sixth electrodes being provided to sandwich the second electrode, the first, second, fifth and sixth electrodes being electrically connected with one another, and the third and fourth electrodes being electrically connected with each other and electrically independent from the first, second, fifth and sixth electrodes;
a semiconductor layer provided between one of the third and fourth electrodes and one of the fifth and sixth electrodes; and
a first interconnect provided on the second, fifth and sixth electrodes and on the semiconductor layer.

2. The device of claim 1, wherein the first interconnect extends in the first direction.

3. The device of claim 1, wherein
the semiconductor layer includes first and second semiconductor layers having a first conductivity type, and a third semiconductor layer provided between the first and second semiconductor layers and having a second conductivity type, and
the first interconnect is provided on the first, second and third semiconductor layers.

4. The device of claim 1, wherein the first interconnect includes a metal layer provided on the second, fifth, and sixth electrodes without interposing a semiconductor layer.

5. The device of claim 1, wherein the first interconnect is electrically insulated from the third and fourth electrodes.

6. The device of claim 1, wherein the first interconnect is electrically connected with the second, fifth and sixth electrodes.

7. The device of claim 1, further comprising a second interconnect provided on the first electrode to be sandwiched between the third and fourth electrodes.

8. The device of claim 7, wherein the second interconnect extends in the first direction.

9. The device of claim 7, wherein the second interconnect includes a metal layer provided on the first electrode without interposing a semiconductor layer.

10. The device of claim 7, wherein the second interconnect is electrically insulated from the third and fourth electrodes.

11. The device of claim 7, wherein the second interconnect is electrically connected with the first electrode.

12. The device of claim 7, further comprising a third interconnect provided on the third and fourth electrodes, and extending in a second direction which is different from the first direction.

13. The device of claim 12, wherein an end portion of the first electrode is positioned on the same side as end portions of the fifth and sixth electrodes relative to the third interconnect.

14. The device of claim 12, wherein an end portion of the second electrode is positioned on the same side as end portions of the fifth and sixth electrodes relative to the third interconnect.

15. The device of claim 1, further comprising a third interconnect provided on the third and fourth electrodes, and extending in a second direction which is different from the first direction.

16. The device of claim 15, wherein the third interconnect includes:
a first region extending in the second direction; and
a second region positioned on the same side as end portions of the fifth and sixth electrodes relative to the first region, and provided on end portions of the third and fourth electrodes.

17. The device of claim 15, wherein an end portion of the first electrode is positioned on an opposite side of end portions of the fifth and sixth electrodes relative to the third interconnect.

18. The device of claim 15, wherein an end portion of the second electrode is positioned on an opposite side of end portions of the fifth and sixth electrodes relative to the third interconnect.

19. The device of claim 15, further comprising a fourth interconnect provided on the first and second electrodes, and extending in the second direction.

20. The device of claim 1, wherein the first, second, fifth and sixth electrodes are source electrodes or electrically connected with the source electrodes, and the third and fourth electrodes are gate electrodes or electrically connected with the gate electrodes.
